(19) United States
(12) Patent Application Publication
(10) Pub. No.: US 2014/0147959 A1
(43) Pub. Date: May 29, 2014

(54) LIQUID METAL EMULSION

(71) Applicants: Olivier Raccurt, Chelieu (FR); Joel Dufourcq, Puyoo (FR); Julien Jouhannaud, Volgre (FR); Olivier Poncelet, Grenoble (FR); Flore Sonier, Vaulnaveys Le Bas (FR); Maryline Roumanie, Décines-Charpieu (FR)

(72) Inventors: Olivier Raccurt, Chelieu (FR); Joel Dufourcq, Puyoo (FR); Julien Jouhannaud, Volgre (FR); Olivier Poncelet, Grenoble (FR); Flore Sonier, Vaulnaveys Le Bas (FR); Maryline Roumanie, Décines-Charpieu (FR)

(73) Assignee: Commissariat A L'Energie Atomique Et Aux Energies Alternatives, Paris (FR)

(21) Appl. No.: 13/819,300

(22) PCT Filed: Aug. 24, 2011
(86) PCT No.: PCT/IB11/53719

§ 371 Date: Mar. 13, 2013

(30) Foreign Application Priority Data
Aug. 26, 2010 (FR) 10 03453

(51) Int. Cl. H01L 31/032; H01L 31/18

(52) U.S. Cl. CPC H01L 31/0322; H01L 31/18
USPC 438/95; 252/512

(57) ABSTRACT

The invention relates to a liquid metal emulsion. The emulsion according to the invention includes a liquid metal selected from among gallium, indium, and the alloys thereof, and a solvent that is an alkanethiol. The invention is useful in particular in the field of manufacturing thin films.

The invention relates to an emulsion comprising droplets of an indium and/or gallium liquid metal in suspension in a solvent, to its process of manufacture and to its uses.

The use of layers, in particular thin layers, typically of a thickness of 1 to 5 μm, of Cu—In—Ga—S or Cu—In—Ga—Se (CIGS) alloy for photovoltaic conversion applications has experienced in the last few years a very strong revival of interest from the industrial viewpoint.

Thus, the deposition of thin CIGS layers on flexible substrates for the preparation of photovoltaic cells is the subject of great research and development activity.

Currently, the depositions of the active CIGS layer are generally carried out by processes generally comprising two steps.

The first step of these processes consists in depositing a more or less amorphous layer of copper-indium-gallium, optionally with sulfur, by vacuum cathode sputtering, and the second step is a step of annealing under a selenium or sulfur atmosphere in order to obtain, if possible, on the one hand, the crystallization of the layer and, on the other hand, the stoichiometry between the different elements.

This stoichiometry is very important as it determines the efficiency of photovoltaic conversion of the layer.

Thus, these processes require the use of vacuum chambers, which requires treatment of the substrates per wafer, indeed even in small batches.

These processes do not make possible continuous deposition of a layer, for example on a production line.

There also exist other methods for the deposition of a CIGS layer not using vacuum and in which the copper, indium, gallium, sulfur or selenium precursors are either in the form of a powder, for example obtained by mechanical grinding, or nanoparticles, or ionic solutions.

These precursors are subsequently employed in solution, by vaporization techniques, the conventional spin coating method or printing processes, such as screen printing, paste coating, and the like.

When mechanically ground powders are used, the layers obtained result in cells which have low efficiencies, which is explained by the difficulty in obtaining, by grinding, powders with a diameter of less than one micron and also by the dispersion in the sizes of the particles thus obtained, the consequence of which is that the layers deposited by screen printing remain not very dense and not very homogeneous, even after a sintering step under N₂ at high temperature.

In order to obtain powders having grains with a diameter of less than one micron with a good dispersion in the size of the particles, research was then directed at nanoparticles. However, Cu, In and Ga nanoparticles are difficult to obtain. This is because the conventional grinding of metals, such as Ga or In, cannot be carried out as a result of their low melting point, resulting in the formation of paste rather than particles, and all the more so for nanoparticles. Furthermore, the grinding also results in the formation of a cold-worked surface layer generally oxidized at the surface, which is highly unfavorable for use in the context of a recrystallization thermal annealing under a selenium-comprising atmosphere.

When the precursors are ionic solutions, there is no step of chemical or mechanical synthesis of the precursors.

This is because the elements Cu, In and Ga are introduced in the form of commercial ionic salts.

The technological solutions presented in the literature differ from one another in the nature of the counterions of the ionic salts and in the choice of the solvents used to formulate the precursor inks.

The use of salts of chloride and/or nitrate type is very widespread in the literature.

Thus, the Zurich Federal Polytechnic School (ETHZ) proposed, in 2005, a method for the low cost manufacture of solar cells by paste coating a solution of Cu(NO₃)₂, InCl₃ and Ga(NO₃)₃, followed by a step of selenization at 550° C. in a tubular furnace. The yield of the CIGS/ZnO/ZnO—Al cells is reported as being 6.7%.

This method is described by Kaelin et al. in Low cost CIGS solar cells by paste coating and selenization, Thin Solid Films, 480-481 (2005), 486-490.

However, these cells have a relatively low output.

Park et al. in Synthesis of CIGS absorber layers via paste coating, Jour. of Crystal Growth (2009), then proposed for the introduction of selenium no longer in the gas phase but, during a thermal annealing, in the form of the soluble precursor SeCl₄.

In this process, an ink is formulated from the ionic salts Cu(NO₃)₂, In and SeCl₄ in a mixture of solvents consisting of ethanol+terpineol+ethyl cellulose. The layer of absorber is deposited by paste coating, raised in temperature to 200° C. under ambient atmosphere in a first step and then raised to between 300° C. and 500° C. under a stream of H₂ (5%)/Ar.

However, this study reveals that numerous organic residues remain in the layer after the annealing steps.

Provision has also been made to work with the element sulfur S rather than with selenium Se.

For this, thiourea SC(NH₂)₂ is used as solvent and precursor of the element sulfur.

Such processes are described by Peza-Tapia et al. in Electrical characterization of Al, Ag and In contacts on CuInS2 thin films deposited by spray pyrolysis, Solar Energy Mater. & Solar Cell, 93 (2009), 544-548, and Kijatkina et al. in CuInS₂ sprayed films on different metal oxide underlayers, Thin Solid Films, 431-432 (2003), 105-109.

In these processes, the CuCl₂ and InCl₃ salts are dissolved in thiourea SC(NH₂)₂ and vaporized over a substrate.

The post-thermal annealing X-ray diffraction (XRD) analysis of the layers thus deposited indeed confirms the presence of a predominant crystalline phase of chalcopyrite CIS but also that of undesirable components crystalline CuₓS, CuCl and In₂S₃, as described by Chen et al. in Preparation and characterization of copper indium disulfide films by facile chemical method, Mater. Sc. & Eng. B, 139 (2007), 88-94.

Copper acetate Cu(CH₃COO)₂ and indium acetate In(CH₃COO)₃ can also be used as precursors in the formation of the CIS layer. Dissolved in a diethanolamine triethanolamine+propanol+ethanol solvent mixture, they are deposited by spin coating in several successive layers, with an intermediate annealing at 300° C. between each layer. In order to obtain the final CIS layer, it is necessary to reduce the copper and indium and to introduce sulfur or selenium. These steps can be carried out by the conventional sequence of a reduction under H₂ (5%)+N₂ and a sulfurization at 500° C., as described by Lee et al. in CuInS₂ thin films deposited by sol-gel spin coating method, Thin Solid Films, 516 (2008), 3862-3864, or, more normally, in a single step, in a tubular furnace comprising a source of sulfur, under a reducing stream of ethanol-N₂, as described by Todorov et al. in CuInS₂ films for photovoltaic applications deposited by a low-cost method, Chem. Mater. (2006), 18, 3145-3150.

Milliron et al., Solution processed metal chalcogenide films for p-type transistors, Chem. Mater. (2006), 18, 587-590, describe a protocol for preparing a solution which makes possible the direct use of sulfur-comprising and selenium-comprising precursors, which makes it possible to suppress the step of removing the counterions.

The dissolution of Cu₂S, In₂Se₃, S and Se in hydrazine, which is a powerful reducing agent, forms an ideal aqueous solution for depositions by the conventional spin coating method.

The solution is deposited by spin coating on a glass+molybdenum substrate, in successive layers, until a thickness of 500 nm is obtained.

A heat treatment at 350° C. finalizes the formation of the layer of absorber.

All these steps are carried out under an inert atmosphere.

The complete cell CISSe/CdS/ZnO/ITO exhibits an output of 3.5%, as recorded by Hou et al. in “Solution processed chalcopyrite thin film solar cell”, (2008).

Thus, the processes for deposition of a thin layer of Cu—In—Ga—X alloy where X is S or Se all exhibit different disadvantages: either the use of processes employing a vacuum, or the use of salts which are difficult to subsequently remove, or the use of nanoparticles which are difficult to manufacture, or the use of explosive products, or do not make it possible to obtain good conversion yields, or also have to be produced under an inert atmosphere.

The invention aims to overcome the disadvantages of the processes of the prior art by providing a process which does not employ vacuum, which makes it possible to obtain good conversion yields, which makes it possible to obtain the desired stoichiometry and which minimizes or even eliminates the use of a metal salt and which in addition can be carried out in the ambient atmosphere (under air).

To this end, the invention proposes to use an emulsion of an indium and/or gallium liquid metal to form the Cu—In—Ga—X layer, where X is S or Se, this emulsion comprising droplets of the liquid metal in a solvent which is an alkanethiol or aliphatic mercaptan.

It had already been proposed to use a liquid metal or a liquid alloy in suspension in a solvent but in order to synthesize solid metal particles and not, as in the invention, in order to form thin films.

Thus, Wang et al. in Bottom-Up and Top-Down Approaches to the Synthesis of Monodispersed Spherical Colloids of Low Melting-Point Metals, Nano Letters, (2004), 4 (10), pp. 2047-2050, describe a process for the synthesis of bismuth particles by heating in diethylene glycol above the melting point of the metal bismuth powder. With magnetic stirring and with the help of poly(vinylpyrrolidone) (PVP), there is formation of monodisperse beads of metal bismuth, after quenching in ethanol to set the emulsion formed.

Henderson et al. in Low-Temperature Solution-Mediated Synthesis of Polycrystalline Intermetallic Compounds from Bulk Metal Powders, Chem. Mater. (2008), 20, 3212-3217, present a similar method for the formation of bimetallic alloy.

The difficulty lies, in the invention, in obtaining an emulsion of an indium or gallium liquid metal or of an In—Ga alloy or a suspension of copper particles in an emulsion of an indium or gallium liquid metal or of an In—Ga—Cu alloy which is stable in order to be able to be applied by paste coating, spraying or spin coating methods. By “stable” it is meant not only a physical stability, that is to say the absence of settling or separation of the droplets of the metal of the constituents of the In—Ga alloy and of the Cu particles, but also a chemical stability, that is to say that the metal or the alloy is not oxidized during the various steps of its manufacture and of the formation of a thin film or of a device comprising this thin film.

Consequently, the invention provides an emulsion comprising droplets of liquid metal and a solvent, characterized in that:
the metal is chosen from indium (In), gallium (Ga) and the alloys of these metals,
the solvent is chosen from:
   an alkanethiol of following formula 1:

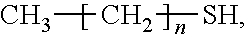

an alkanethiol ester of following formula 2:

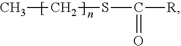

and
an alkanethiol propionic ether of following formula 3:

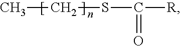

in which n is between 5 and 19 inclusive and R is a methyl or ethyl group, and
in that it additionally comprises a surfactant.

Preferably, the surfactant is chosen from surfactants comprising at least one thiol functional group, cetyltrimethylammonium bromide (CTAB), a surfactant of the family of the sorbitan monostearates, preferably Span®, a surfactant of the family of the polysorbates, preferably Tween®, an octylphenol ethoxylate surfactant, preferably Triton® X100, a surfactant comprising a pyrrolidol group and the mixtures of these.

Preferably, this emulsion comprises 90% of the liquid metal droplets which have a mean diameter of less than 1 μm.

Preferably, the thiol-comprising solvent has a boiling point greater by at least 5° C. than the melting point of the metal or of the metal alloy.

Preferably again, the solvent is dodecanethiol.

Still preferably, the surfactant is Triton® X.

In a first embodiment, the metal is indium.

In a second embodiment, the metal is gallium.

In a third embodiment, which is preferred, the metal is an alloy of indium and gallium.

In this case, preferably, the alloy of indium and gallium comprises 70% by weight of indium and 30% by weight of gallium, with respect to the total weight of indium and gallium.

In a fourth embodiment, which is also preferred, the emulsion additionally comprises particles of metal copper Cu(0) having a size (greatest dimension) of between 10 nm and 1 μm, preferably between 10 nm and 500 nm (measured with a scanning electron microscope (SEM), with a transmission electron microscope (TEM) or by dynamic light scattering (DLS)), or of a precursor of the latter in the organometallic form or in the salt form.

In this case, preferably, the metal copper precursor is copper chloride (CuCl₂), copper nitrate (Cu(NO₃)₂), a copper carboxylate of formula Cu(OOCR)₂, where R is a linear C₁ to C₃ alkyl group, preferably copper acetate, a copper β-diketonate of formula Cu(R₁COCH₂COR₂)₂, where R₁ and R₂ are, preferably, copper acetylacetonate, a copper alkoxide of formula Cu(OR³)₂, in which R₃ is a linear C₁ to C₄ alkyl, or of formula Cu(OR₄)₂NR₅, in which R₄ is a linear C₁ to C₂ alkyl and R₅ is H or a linear C₂ alcohol group or a linear C₁ to C₄ alkyl, an alcohol of formula HOCH₂CH₂NR₆R₇, with R₆ and R₇ which are identical or different and are chosen, independently of one another, from H, Me, Et, Pr or Bu.

Still in this case, more preferably, the metal copper precursor is chosen from the copper alkoxides Cu (OCH₂CH₂)₂NH, Cu (OCH₂CH₂)₂NnBu or Cu (OCH₂CH₂)₂NEt or a mixture of these.

Still in this case, and also preferably, the surfactant/solvent ratio by volume is between 10⁻⁴ and 10⁻² inclusive.

The invention also provides a process for the manufacture of an emulsion according to the invention, comprising droplets of a liquid metal, characterized in that it comprises the following steps:

a) introduction of a metal chosen from indium, gallium and the alloys of these metals into a solvent chosen from:
an alkanethiol of following formula 1:

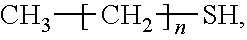

an alkanethiol ester of following formula 2:

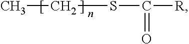

and
an alkanethiol propionic ether of following formula 3:

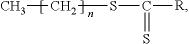

in which n is between 5 and 19 inclusive and R is a methyl or ethyl group,
b) heating the suspension obtained in step a) to a temperature greater than the melting point of the metal and lower than the boiling point of the solvent,
c) addition of a surfactant,
d) application of ultrasound for 15 minutes, while maintaining the same temperature as in steps b) and c), with a 20 kHz probe, amplitude of 75%,
e) cooling the emulsion obtained in step d), and
f) application of ultrasound for 15 minutes, at ambient temperature, with a 20 kHz probe, amplitude 20%.

The term “ambient temperature” is intended to mean, in the invention, a temperature between 15 and 30° C. inclusive.

In a first embodiment, the metal is indium and the heating temperature in steps b), c) and d) is 180° C.

In a second embodiment, the metal is gallium and the heating temperature in steps b), c) and d) is 70° C.

In a third embodiment, which is preferred, the metal is an alloy of indium and gallium and, in step a), particles of a preformed alloy of indium and gallium or particles of indium and particles of gallium in the desired proportions are introduced, or else a liquid gallium emulsion according to the invention is mixed with a liquid indium emulsion according to the invention, in the desired proportions of indium and gallium to form the desired alloy of indium and gallium, and the heating temperature in steps b), c) and d) is 180° C.

The surfactant is preferably chosen from surfactants optionally having at least one thiol functional group, cetyltrimethylammonium bromide (CTAB), a surfactant of the family of the sorbitan monostearates, preferably Span®, a surfactant of the family of the polysorbates, preferably Tween®, an octylphenol ethoxylate surfactant, preferably Triton® X100, a surfactant comprising a pyrrolidol group and the mixtures of these.

step b) preferably lasts between 30 minutes and 90 minutes.

With regard to the cooling of step c), it can be a natural or forced cooling.

In all cases, the process of the invention preferably additionally comprises, after step c), a step of addition of particles of copper or of a copper precursor chosen from particles of copper chloride (CuCl₂), copper nitrate (Cu(NO₃)₂), a copper carboxylate of formula Cu(OOCR)₂, where R is a linear C₁ to C₃ alkyl group, preferably copper acetate, a copper β-diketonate of formula Cu(R₁COCH₂COR₂)₂, where R₁ and R₂ are, preferably copper acetylacetonate, a copper alkoxide of formula Cu(OR₃)₂, in which R₃ is a linear C₁ to C₄ alkyl, or of formula Cu(OR₄)₂NR₅, in which R₄ is a linear C₁ to C₂ alkyl and R₅ is H or a linear C₂ alcohol group or a linear C₁ to C₄ alkyl, an alcohol of formula HOCH₂CH₂NR₆R₇, with R₆ and R₇ which are identical or different and are chosen, independently of one another, from H, Me, Et, Pr or Bu.

Preferably, the copper precursor is chosen from the copper alkoxides Cu(OCH₂CH₂)₂NH, Cu(OCH₂CH₂)₂NnBu or Cu(OCH₂CH₂)₂NEt or a mixture of these.

Also preferably, the solvent is dodecanethiol.

Preferably again, the surfactant is Triton® X100.

The invention also provides a process for the deposition of a film made of a metal chosen from indium and gallium and the alloys of these, characterized in that it comprises the following steps:

a) deposition, on at least one surface of a substrate, of an emulsion of the chosen metal, and
b) heat treatment of the at least one surface.

Preferably, the deposition step a) is carried out by paste coating, screen printing or spraying said emulsion.

Also preferably, the heat treatment step b) is carried out at a temperature of greater than 120° C. and of less than 300° C. for a period of time of between 10 minutes and 60 minutes.

In addition, the invention provides a process for the deposition of a Cu—In—Ga—X film, where X is S or Se, characterized in that it comprises the following steps:

a) deposition, on at least one surface of a substrate, of an In—Ga—Cu emulsion, and
b) heat treatment of said at least one surface in the presence of vapor of X.

The invention also provides a process for the manufacture of an active layer of a photovoltaic device, characterized in that it comprises a step of deposition of a Cu—In—Ga—X film, where X is S and/or Se, or a mixture of the two, on at least one surface of a substrate by the abovementioned process of the invention.

The invention also provides a process for the manufacture of a photovoltaic device, characterized in that it comprises a step of deposition of a Cu—In—Ga—X film, where X is S or Se, on at least one surface of a substrate by the abovementioned process according to the invention.

In a first embodiment, the photovoltaic device is a photovoltaic battery or a photovoltaic panel, or a photovoltaic cell.

Finally, the invention provides for the use of an emulsion according to the invention for the deposition of a film of a metal chosen from indium and gallium and the alloys of these on the surface of at least one substrate.

The invention will be better understood and other characteristics and advantages of the latter will become more clearly apparent in the light of the explanatory description which follows and which is made with reference to the figures, in which:

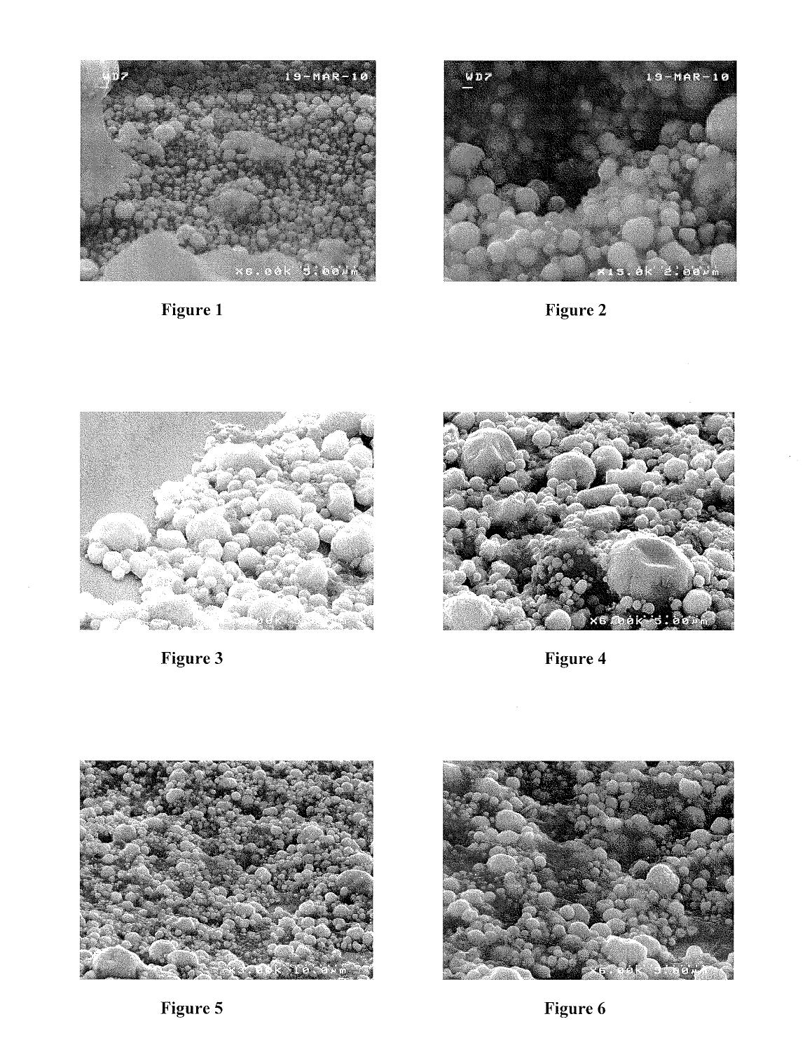

FIGS. 1 and 2 are photographs taken with a scanning electron microscope of an indium emulsion according to the invention,

FIGS. 3 and 4 are photographs taken with a scanning electron microscope of an indium emulsion prepared by applying ultrasound only once, and this at a power lower than that used in the process according to the invention,

FIGS. 5 and 6 are photographs taken with a scanning electron microscope of an indium emulsion prepared by applying ultrasound solely during the cooling of the emulsion,

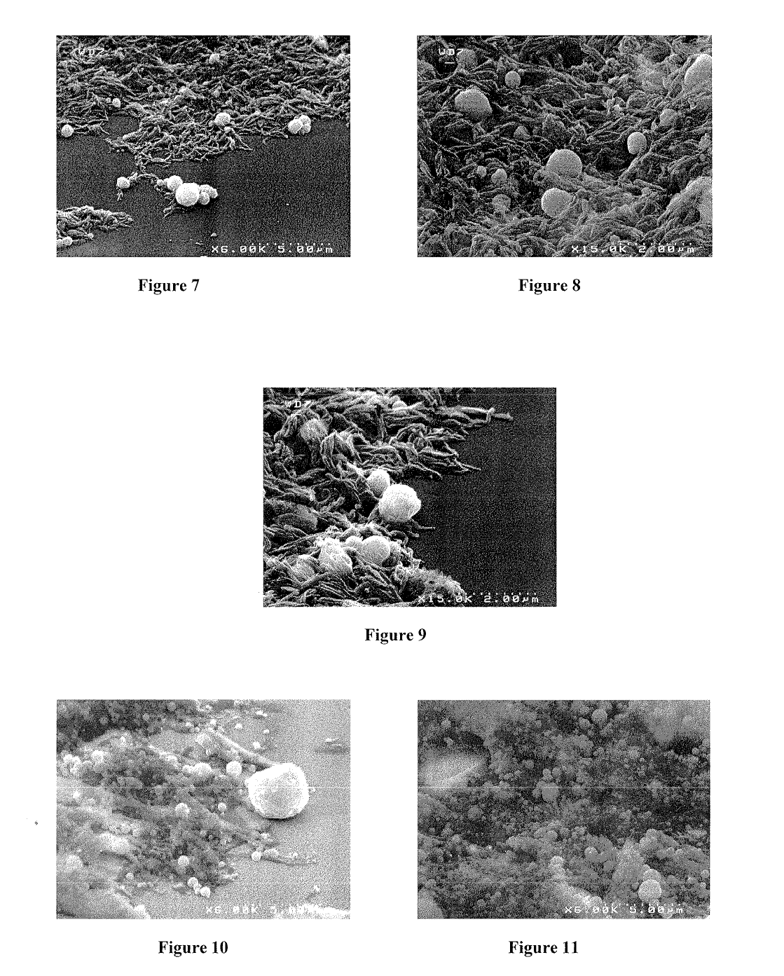

FIGS. 7, 8 and 9 are photographs taken with a scanning electron microscope of an indium emulsion prepared by applying ultrasound solely during the heating of the emulsion,

FIGS. 10 and 11 are photographs taken with a scanning electron microscope of an indium emulsion prepared by applying ultrasound once more, at the end of the protocol, with respect to the indium emulsion prepared according to the invention,

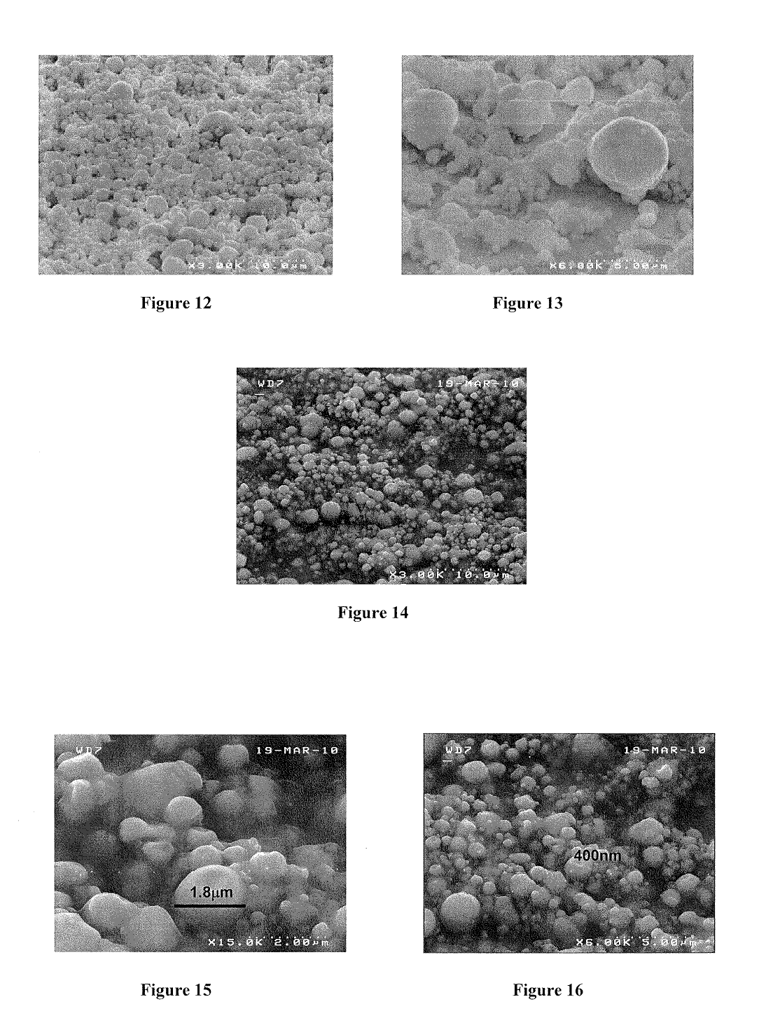

FIGS. 12 and 13 are photographs taken with a scanning electron microscope of an indium emulsion prepared without surfactant and at a temperature of 150° C.,

FIGS. 14, 15 and 16 are photographs taken with a scanning electron microscope of an indium emulsion prepared by heating at 150° C. but while adding a surfactant,

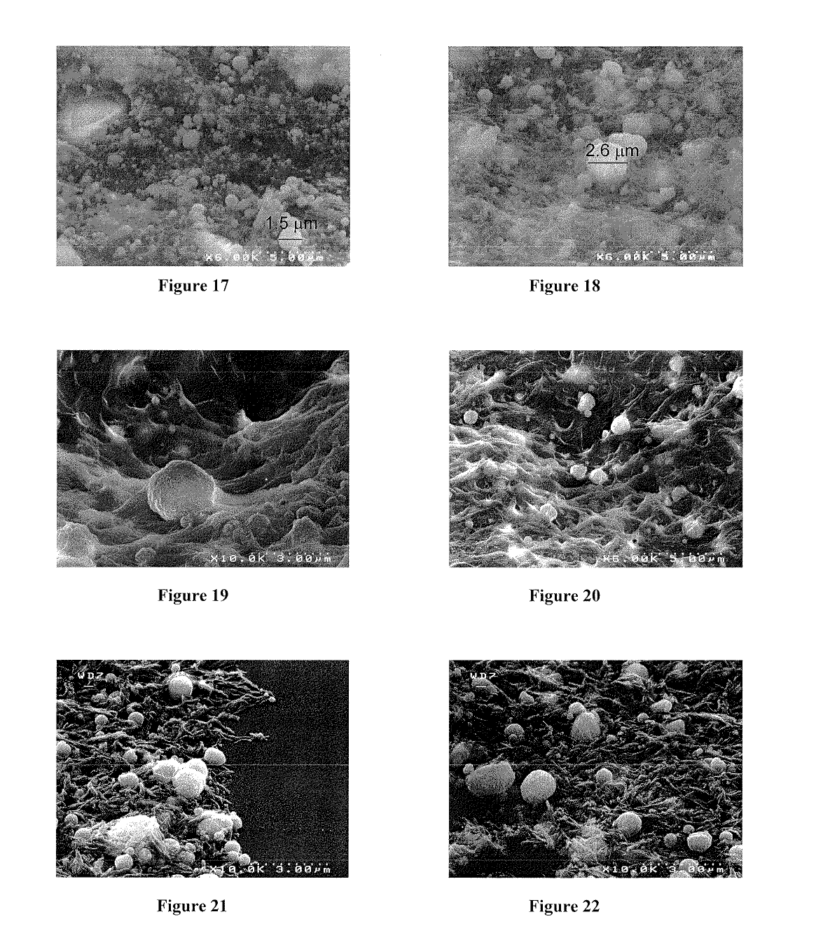

FIGS. 17 and 18 are photographs taken with a scanning electron microscope of an indium emulsion prepared by applying ultrasound just once and by quenching the emulsion with water cooled to 0° C.,

FIGS. 19 and 20 are photographs taken with a scanning electron microscope of an indium emulsion prepared like the emulsion represented in FIGS. 17 and 18 above except for the quenching, which was carried out with liquid nitrogen,

FIGS. 21 and 22 are photographs taken with a scanning electron microscope of an indium emulsion prepared like the emulsions represented in FIGS. 17, 18, 19 and 20 but without carrying out the quenching for the cooling and while using twice as much surfactant,

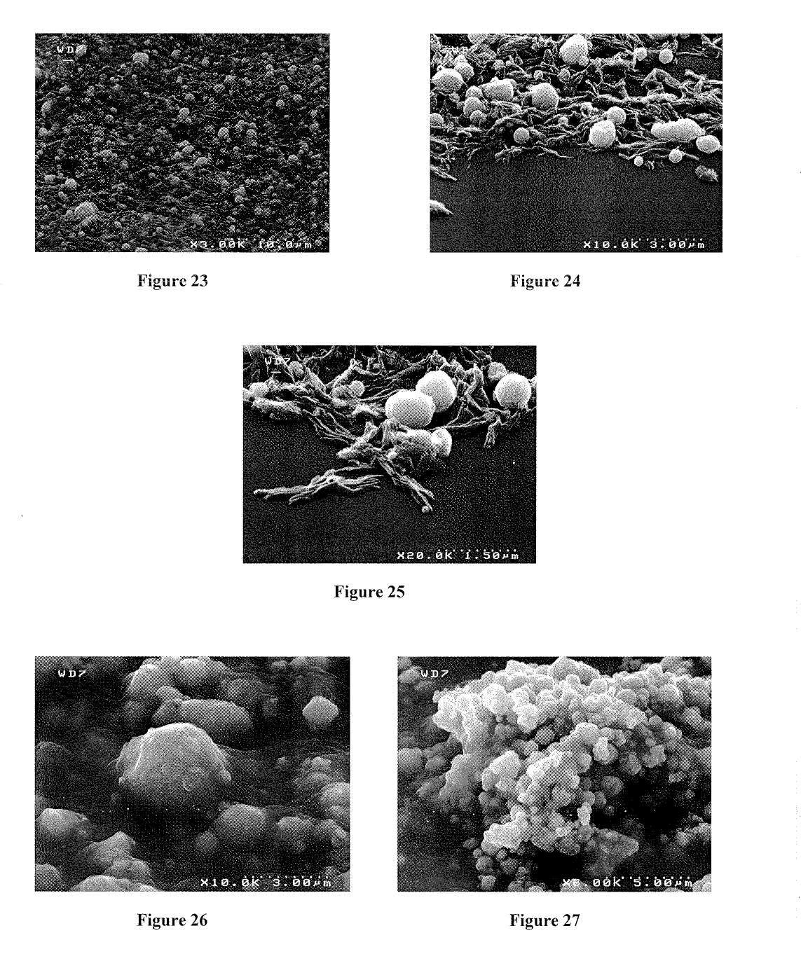

FIGS. 23, 24 and 25 are photographs taken with a scanning electron microscope of an indium emulsion prepared like the emulsion represented in FIGS. 21 and 22 but while using one fourth as much surfactant,

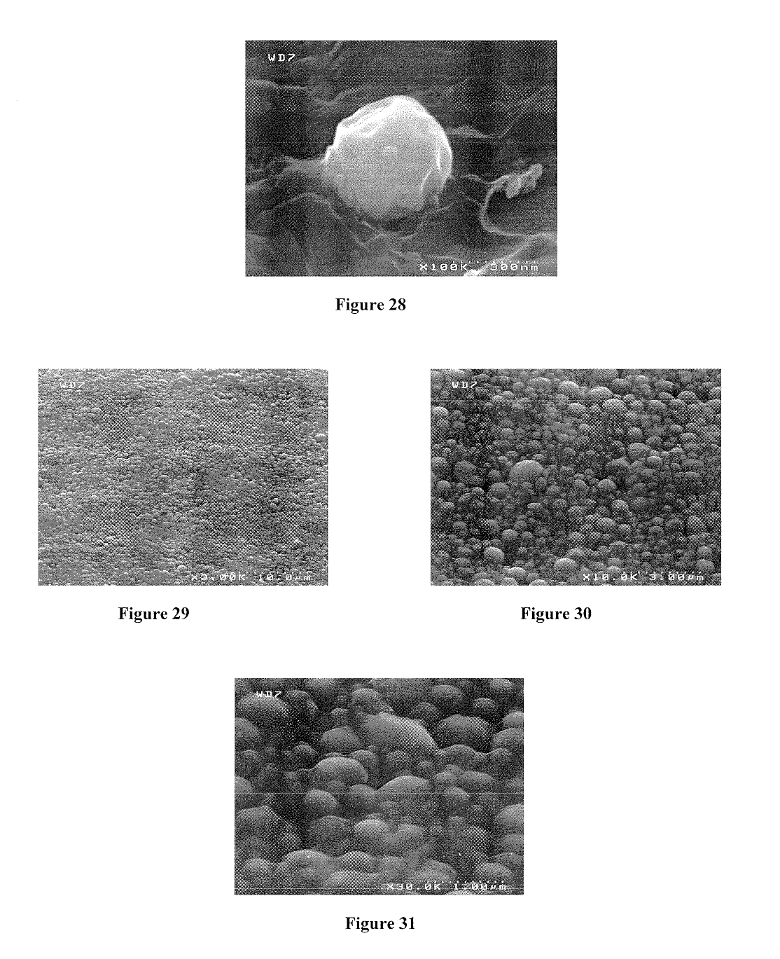

FIGS. 26, 27 and 28 are photographs taken with a scanning electron microscope of an indium emulsion prepared like the emulsion represented in FIGS. 19 and 20 but while adding copper at the end of the ultrasound,

FIGS. 29, 30 and 31 are photographs taken with a scanning electron microscope of a gallium emulsion prepared by the process according to the invention,

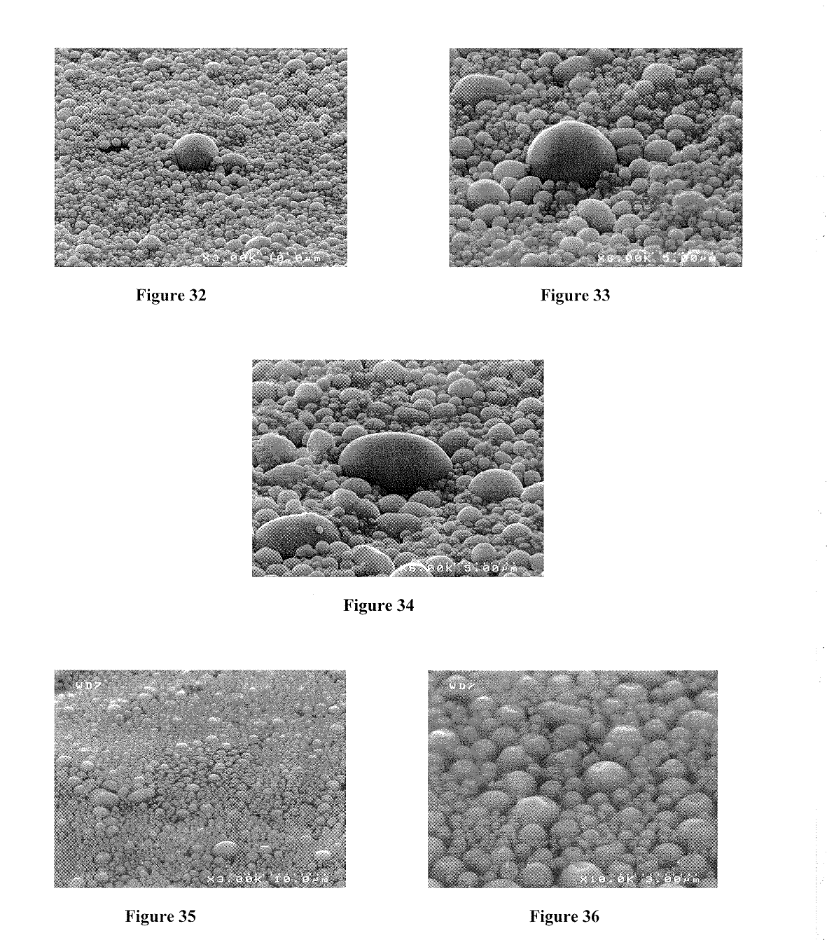

FIGS. 32, 33 and 34 are photographs taken with a scanning electron microscope of a gallium emulsion prepared without a heating period before and during the application of the ultrasound,

FIGS. 35 and 36 are photographs taken with a scanning electron microscope of a gallium emulsion prepared without applying ultrasound under cold conditions,

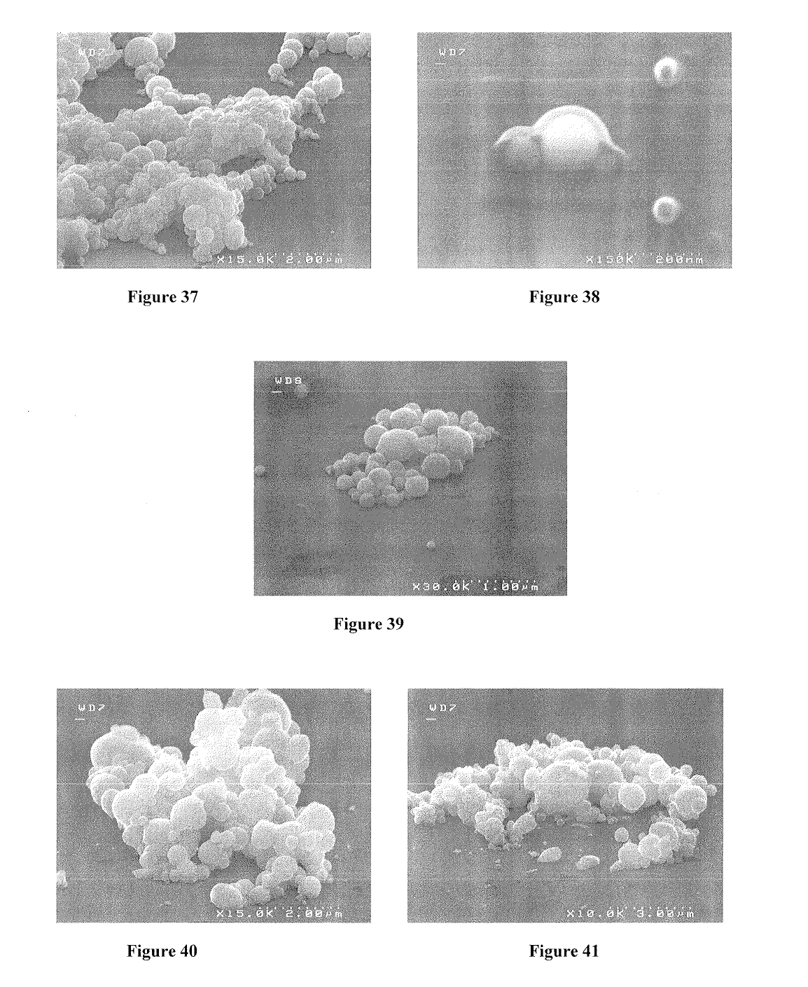

FIGS. 37, 38 and 39 are photographs taken with a scanning electron microscope of an indium and gallium emulsion comprising 30% by weight of gallium and 70% by weight of indium prepared by the process of the invention, and

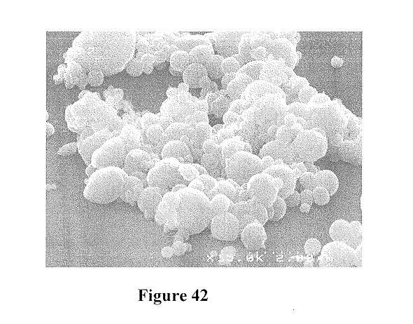

FIGS. 40, 41 and 42 are photographs taken with a scanning electron microscope of an indium and gallium emulsion comprising 30% by weight of gallium and 70% by weight of indium prepared by the process of the invention, additionally comprising a final step of application of ultrasound under cold conditions.

The invention lies in the formation and the use of an emulsion of a metal chosen from In, Ga and an alloy comprising them, liquid, in a solvent.

Thus, a first subject matter of the invention is an emulsion which comprises droplets of In and/or Ga liquid metal in suspension in a solvent.

In order for the In and/or Ga metal to be liquid, it is necessary for it to be molten, that is to say that it is necessary for the emulsion to be brought to a temperature at least equal to the melting point of the In—Ga alloy.

However, the solvent must have a boiling point greater than the melting point of the In—Ga alloy.

These temperatures will, of course, depend on the nature of the metal.

The melting point of indium is 156° C. That of gallium is 30° C. For an In—Ga alloy comprising 70% by weight of indium and 30% by weight of gallium, the melting point is 120° C.

The solvent must thus have a boiling point of greater than 120° C., preferably greater than 130° C., for the abovementioned In—Ga alloy but of greater than 156° C. for In and of greater than 30° C. for Ga.

This alloy is particularly appropriate as cells based on CIGS having the best performance require these relative proportions of Ga and In in order to have an optimum band gap.

In addition, this solvent must, according to the invention, be a thiol-comprising solvent.

This is because such a solvent makes it possible to form a passivation layer around the droplets of liquid metal, which then becomes insensitive to surface oxidation during the various heat treatments which will subsequently be carried out, up to the formation of the final device in which they will be used.

Otherwise stated, with the choice of such a solvent for the formation of the liquid metal emulsion according to the invention, it is no longer necessary to work under an inert atmosphere, even after the resolidification of the metal.

The preferred thiol-comprising solvents have one of the following formulae 1 to 3:
an alkanethiol of following formula 1:

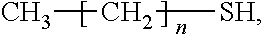

an alkanethiol ester of following formula 2:

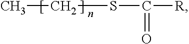

and
an alkanethiol propionic ether of following formula 3:

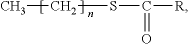

in which n is between 5 and 19 inclusive and R is CH₃ or —CH₂—CH₃.

Preferably, the solvent is dodecanethiol.

The emulsion of the invention also comprises a surfactant which makes possible the formation and the stabilization of the emulsion and also the reduction in the size of the liquid metal droplets.

Thus, preferably, 90% of the liquid metal droplets will have a size of less than 1 μm.

A person skilled is able to determine which surfactant to use.

However, nonionic surfactants are preferred.

Thus, the preferred surfactants for the emulsion of the invention are cetyltrimethylammonium bromide (CTAB), surfactants having thiol functional groups, such as dodecanethiol or octadecanethiol, molecules having a pyrrolidol group, surfactants of the family of the polysorbates, such as Tween®, surfactants of the family of the sorbitan monostearates, such as Span® surfactants, or octylphenol ethoxylate surfactants, such as Triton® X100.

The following are particularly preferred:

1) the following surfactants of the family of the dithianes:
a) 1,4-dithiane-2,5-diol

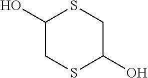

b) 2,5-dihydroxy-2,5-dimethyl-1,4-dithiane

### Formula: C₆H₁₂O₂S₂

Molecular weight: 180.29 g/mol
Synonyms: 2,5-dimethyl-1,4-dithiane-2,5-diol or 1-mercaptopropanone (dimer) or cyclodithalfarol-705 or 2,5-dimethyl-2,5-dihydroxy-p-dithiane
c) 2-methyl-1,3-dithiane

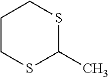

d) ethyl 1,3-dithiane-2-carboxylate

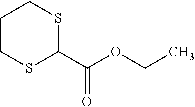

e) trans-4,5-dihydroxy-1,2-dithiane

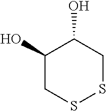

2) the following surfactants of the family of the thiols:

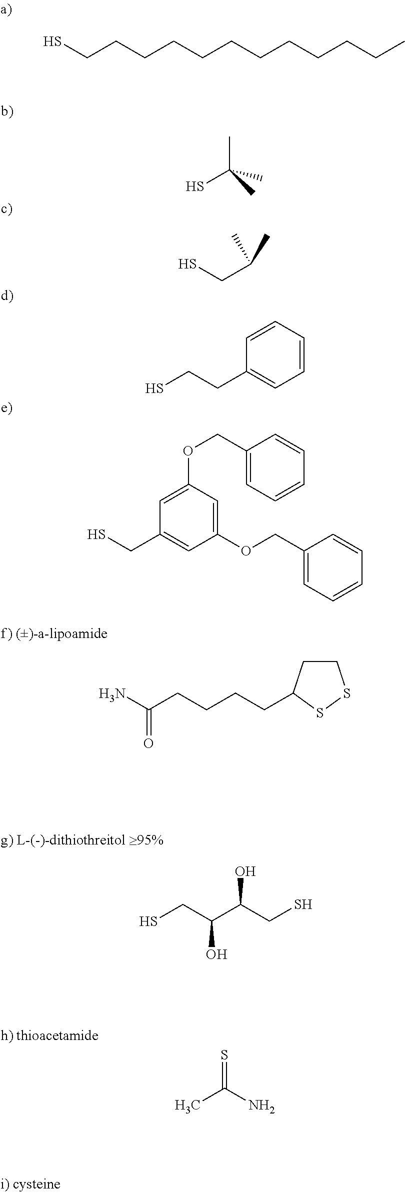

Erreur ! Référence de lien hypertexte non valide.
j) dodecylthio glycopyranoside sulfates
3) thiol-comprising surfactants of formula CH₃(CH₂)ₙS(CH₂)ₘN(CH₃)₃⁺Br⁻, in which n and m are as shown in the following table 1:

TABLE 1
Structure of the thiol-comprising surfactants
CH₃(CH₂)ₙS(CH₂)ₘN(CH₃)₃⁺Br⁻

| Thio surfactant | n | m |
|---|---|---|
| 3-3 | 2 | 3 |
| 2-10 | 1 | 10 |
| 6-6 | 5 | 6 |
| 6-8 | 5 | 8 |
| 8-6 | 7 | 6 |
| 8-8 | 7 | 8 |

In addition, a thiol-comprising surfactant comprising two sulfur atoms having the structure CH₃(CH₂)₅S(CH₂)_{6S}(CH₂)₆N(CH₃)₃⁺Br⁻ is also preferred.

The mixtures of these surfactants can also be used to obtain a stable emulsion and to reduce the size of the droplets.

It is also possible to vary the viscosity (concentration and size of the particles) and the interfacial tension between the solvent and the liquid alloy in order to minimize the size of the droplets formed.

The greater the density of the solvent in kg/m³, the more possible it will be to obtain a high content of In and/or Ga charge in the emulsion of the invention in order for it to remain stable.

This emulsion, comprising droplets of In and/or Ga liquid metal in suspension in a solvent, can be used for the deposition of an In and/or Ga film on at least one surface of a substrate by applying this emulsion, by paste coating, by screen printing or else by spraying, on the desired surface.

Copper can then be introduced by any method known to a person skilled in the art into the film thus formed and this film can subsequently be selenized or sulfurized by any method known to a person skilled in the art, such as by annealing, under an atmosphere of selenium or sulfur vapor, the indium-gallium-Cu film obtained.

However, preferably, the copper is introduced into the emulsion of the invention comprising droplets of In and/or Ga liquid metal in suspension in a solvent.

The copper can be introduced, and this is a preferred embodiment of the invention, in the form of particles of metal copper with an oxidation state of 0.

The copper particles preferably have a size of less than 1 μm, preferably of less than 10 nm.

This is because, by introducing the metal copper particles into the emulsion in the desired stoichiometry, the use of a copper precursor which is an inorganic or organic copper salt is avoided, this salt possibly being subsequently difficult to remove during the selenization or sulfurization treatment which will follow.

However, the copper can, of course, be introduced into the emulsion of the invention comprising droplets of In—Ga liquid alloy in suspension in a solvent in the form of its precursors known in the art, such as copper chloride (CuCl₂), copper nitrate (Cu(NO₃)₂), the copper carboxylate of formula Cu(OOCR)₂, where R is a linear C₁ to C₃ alkyl group, preferably copper acetate, a copper β-diketonate of formula Cu(R₁COCH₂COR₂)₂, where R₁ and R₂ are, preferably copper acetylacetonate, a copper alkoxide of formula Cu(OR₃)₂, in which R₃ is a linear C₁ to C₄ alkyl, or of formula Cu(OR₄)₂NR₅, in which R₄ is a linear C₁ to C₂ alkyl and R₅ is H or a linear C₂ alcohol group or a linear C₁ to C₄ alkyl, an alcohol of formula HOCH₂CH₂NR₆R₇, with R₆ and R₇ which are identical or different and are chosen, independently of one another, from H, Me, Et, Pr or Bu.

The copper carboxylate, β-diketonate and alkoxide precursors can, by heat treatment in a reducing medium, result in the formation of nanoparticles of metal copper with an oxidation state of 0.

Use may be made, as a reducing agent, of alkali metal hydrides, hydrazine, an ascorbate, such as ascorbic acid esters or ascorbic acid, sugars and polyols, such as ethylene glycol, diethylene glycol, propylene glycol, and the like.

Because copper alkoxides are more easily reduced than copper carboxylates or β-diketonates, these precursors will preferably be used in the invention.

Furthermore, they make it possible to obtain, in alcoholic solution and in a reducing medium, copper nanoparticles which can form alloys at the nanometric scale with In—Ga or In and Ga nanodomains or In or Ga nanodomains, without destabilizing the emulsion.

This is because it is very important not to destabilize the emulsion of the invention during the addition of the alcoholic copper alkoxide solution and not to destabilize it during an excessively violent rise in temperature.

A person skilled in the art, whose aim is to obtain an amount of metal copper with an oxidation state of 0, after reduction of the copper alkoxides, will a priori use copper alkoxides comprising a short and straight chain.

However, these alkoxides Cu(OR)₂ with R=Me or Et are solid polymers at ambient temperature and are sensitive to hydrolysis and thus form polymeric hydroxides.

Their polymeric nature limits their solubility.

Consequently, the copper alkoxide solutions added will be diluted, which risks destabilizing the emulsion.

This is why the preferred copper alkoxides of the invention have a longer aliphatic chain with a butyl or hexyl R group.

These alkoxides are viscous liquids at ambient temperature; they can thus be added directly to the emulsion without having to add solvent, which constitutes a not insignificant advantage: what has not been added will not have to be removed.

In order to further select the copper alkoxides, their percentage of copper by weight is important.

The percentage of copper by weight per type of alkoxide is given in the following table 2:

TABLE 2

| Alkoxide | % Copper |
|---|---|
| Cu(OMe)₂ | 50.61 |
| Cu(OCH₂CH₃)₂ | 41.38 |
| Cu(OCH₂CH₂CH₂CH₃)₂ | 42.49 |
| Cu(OCH₂CH₂)₂NCH₂CH₂OH | 29.89 |
| Cu(OCH₂CH₂)₂NH | 37.70 |
| Cu(OCH₂CH₂)₂NnBu | 28.29 |
| Cu(OCH₂CH₂)₂NEt | 32.33 |

Use will still more preferably be made, among these, of the alkoxides brought together in the following table 3 as they have a temperature for reduction to metal copper with an oxidation state of 0 given in table 3.

TABLE 3

| Alkoxide | Reduction temperature | |
|---|---|---|
| Cu(OCH₂CH₂CH₂CH₃)₂ | 200° | C. |
| Cu(OCH₂CH₂)₂NCH₂CH₂OH | 180° | C. |
| Cu(OCH₂CH₂)₂NH | 100° | C. |
| Cu(OCH₂CH₂)₂NnBu | 70-80° | C. |
| Cu(OCH₂CH₂)₂NEt | 70-80° | C. |

This reduction temperature is important for two reasons:
in the case where it is desired to reduce the copper alkoxide in the emulsion before the paste coating on the substrate, it is advisable not to destabilize this emulsion. It is therefore necessary for this temperature not to be too high, and
in the case where the reduction takes place after the emulsion has been paste coated on its substrate, it is also necessary for the reduction temperature not to be too high as there would be a risk of subliming the copper alkoxide, which would render random the control of the stoichiometry of the film formed.

Specifically, in the invention, the copper precursors described above can be used on the preformed In—Ga film or can be introduced into the emulsion itself.

Thus, the preferred copper precursors to be added to the emulsion before the formation of the film, or after the formation of the In—Ga film, are copper alkoxides of formulae Cu(OCH₂CH₂)₂NH, Cu(OCH₂CH₂)₂NnBu and Cu(OCH₂CH₂)₂NEt as the final amount of copper formed after reduction is high and, furthermore being liquid, they can be added undiluted to the emulsion.

The copper alkoxides used in the invention are copper(II) alkoxides, not copper(I) alkoxides, as their synthesis makes it possible to use less solvent than the synthesis of the copper(I) alkoxides, due to the low solubility of CuCl in alcohol or THF, CuCl resulting in the formation of copper(I) alkoxides.

However, other copper precursors which can be used in the invention, either to be added to the In and/or Ga liquid metal emulsion or to be applied to the preformed In and/or Ga film, are alcohols of formula HOCH₂CH₂NRR′, with R and R′ being identical or different and chosen, independently of one another, from H, Me, Et, Pr or Bu.

This is because these alcohols are highly volatile and thus will form only comparatively little in the way of carbon-based residues in the Cu(In and/or Ga)S or Se layer formed.

Thus, a second subject matter of the invention is an emulsion comprising droplets of indium and/or gallium liquid metal and particles of copper or of copper precursors in suspension in a solvent.

The solvent is here again a thiol-comprising solvent as defined above.

This emulsion can be used for the formation of a thin film of Cu—In—Ga or Cu—In or Cu—Ga alloy on at least one surface of the substrate.

Once this film has been formed, it will be possible to obtain a thin film of Cu—In—X or else Cu—In—Ga—X alloy, where X is equal to S or Se, by sulfurization or selenization of the film obtained.

As above, this sulfurization or selenization can be carried out by a heat treatment of the film or more precisely of the surface of the substrate on which this film is deposited with selenium or sulfur in the vapor form, as is known in the art.

Thus, a third subject matter of the invention is the use of the emulsion of the invention not comprising copper particles for the formation of a film made of In and/or Ga metal on a substrate or for the formation of a Cu—In or Ga—In or Cu—In—Ga film on a surface of a substrate or also to form a film of Cu—In—S or Cu—In—Se or Cu—Ga—S or Cu—Ga—Se or Cu—In alloy on a surface of a substrate and more particularly for the formation of an active layer of a photovoltaic device which can be a photovoltaic battery, cell or a photovoltaic panel.

A fourth subject matter of the invention is the use of the emulsion of the invention comprising copper particles or a copper precursor as described above for the formation of a thin film of Cu—In or Cu—In—S or Cu—In—Se or Cu—Ga or Cu—In—Ga—S or Cu—In—Ga—Se alloy on the surface of a substrate and in particular for the formation of an active layer of a photovoltaic device, such as a photovoltaic battery, cell or panel.

A fifth subject matter of the invention is a process for the deposition of a film made of indium and/or gallium metal which comprises the deposition of an In and/or Ga emulsion according to the invention not comprising copper on at least one surface of a treatment and the heat treatment of this at least one surface.

Preferably, the deposition is carried out by paste coating said emulsion on the surface of the substrate and the heat treatment step is carried out at a temperature of greater than 120° C. for a period of time of 10 to 60 minutes, when the In—Ga alloy is an alloy comprising 70% by weight of indium and 30% by weight of gallium.

When the metal is In, the paste coating step is carried out at a temperature of greater than 160° C. for a period of time of 10 minutes to 60 minutes.

When the metal is Ga, the paste coating step is carried out at a temperature of greater than 30° C. for a period of time of 10 to 60 minutes.

A sixth subject matter of the invention is a process for the deposition of a Cu—In—Ga film on at least one surface of a substrate which comprises the steps of deposition of a film made of In and/or Ga metal according to the process of the fifth subject matter of the invention and then introduction of copper in the stoichiometry desired in this film.

However, a preferred process of the invention for depositing a Cu—In or Cu—Ga or Cu—In—Ga film on at least one surface of a substrate comprises the steps of deposition of an emulsion according to the invention comprising particles of copper or of a precursor of the latter, as described above, on said surface of the substrate and the heat treatment of this surface in order to set the structure of the film deposited. Advantageously, a first heat treatment at 150° C. makes it possible to set the structure of the film and a second heat treatment at 250° C., for example, and in any case at a temperature greater than the boiling point of the solvent, makes possible its removal by evaporation.

In this case, the process according to the invention additionally comprises, after step c), a step of addition of particles of copper or of a copper precursor chosen from particles of copper chloride (CuCl₂), copper nitrate (Cu(NO₃)₂), a copper carboxylate of formula Cu(OOCR)₂, where R is a linear C₁ to C₃ alkyl group, preferably copper acetate, a copper β-diketonate of formula Cu(R₁COCH₂COR₂)₂, where R₁ and R₂ are, preferably copper acetylacetonate, a copper alkoxide of formula Cu(OR₃)₂, in which R₃ is a linear C₁ to C₄ alkyl, or of formula Cu(OR₄)₂NR₅, in which R₄ is a linear C₁ to C₂ alkyl and R₅ is H or a linear C₂ alcohol group or a linear C₁ to C₄ alkyl, an alcohol of formula HOCH₂CH₂NR₆R₇, with R₆ and R₇ which are identical or different and are chosen, independently of one another, from H, Me, Et, Pr or Bu.

Preferably, the copper precursor is chosen from the copper alkoxides Cu(OCH₂CH₂)₂NH, Cu(OCH₂CH₂)₂NnBu or Cu(OCH₂CH₂)₂NEt or a mixture of these.

The preferred solvent is dodecanethiol.

In the same way, the preferred surfactant is Triton® X100.

Preferably, the deposition of the emulsion on the desired surface is carried out by paste coating said emulsion on this surface.

However, it can also be carried out by spraying, according to the usual techniques controlled by a person skilled in the art.

Preferably, when the In—Ga alloy is an alloy comprising 70% by weight of indium and 30% by weight of gallium, the heat treatment is carried out at a temperature of 120° C. for a period of time of 10 to 60 minutes.

A seventh subject matter of the invention is a process for the deposition of a film of Cu—In—Ga—X, where X is S or Se, which comprises the deposition of a Cu—In—Ga film according to one of the processes described above, that is to say by formation of an In—Ga film and then introduction of copper or by direct formation, from the emulsion of the invention comprising copper or a precursor of the latter, of a Cu—In or Cu—Ga or Cu—In—Ga film, on the surface of a substrate and the heat treatment of this surface in the presence of vapor of X, that is to say of sulfur or selenium. Typically, this heat treatment is carried out at between 300° C. and 600° C.

This process can be used for the manufacture of an active layer of a photovoltaic, for the manufacture of a photovoltaic device, such as a photovoltaic battery, cell or panel, and in particular for the deposition of a film made of a metal chosen from indium and gallium.

Thus, an eighth subject matter of the invention comprises the following steps:

a) deposition of an emulsion, according to the invention or obtained by the process of the invention, of a liquid In—Ga—Cu alloy on at least one surface of a substrate, and
b) heat treatment of the at least one surface in the presence of the vapor of X, X being chosen from S and Se.

Preferably, the deposition step a) is carried out by paste coating or spraying said emulsion.

Preferably, in step b), the heat treatment is carried out at between 300° C. and 600° C.

In order to render the invention better understood, a description will now be given, as purely illustrative and nonlimiting examples, of embodiments of the invention.

### EXAMPLE 1

### Manufacture of an Indium Emulsion According to the Invention

The procedure was carried out by applying ultrasound at the end of the protocol.

The protocol used is as follows:
1 g of indium is weighed out in 40 ml of dodecanethiol,
the round-bottomed flask is placed on the heating plate without stirring,
heating is carried out at 180° C. for ¾ hour,
Triton® X100 (250 μl) is added and the mixture is stirred at 180° C. for ¼ hour: the solution becomes gray,
ultrasound is applied for 15 minutes at 200 W/cm² under hot conditions (20 kHz probe),
cooling is allowed to take place, and
ultrasound is applied for 15 minutes at 200 W/cm² under cold conditions.

The emulsion obtained is represented in FIGS. 1 and 2.

### COMPARATIVE EXAMPLE 1

The procedure was carried out as in example 1 but without application of ultrasound under cold conditions.

The protocol used is as follows:
1 g of indium is weighed out in 40 ml of dodecanethiol,
the round-bottomed flask is placed on the heating plate without stirring,
the mixture is heated at 180° C. for ¾ hour,
Triton® X100 (250 μl) is added and the mixture is stirred at 180° C. for ¼ hour: the solution becomes gray,
the round-bottomed flask is moved toward the ultrasound probe and the round-bottomed flask is no longer heated,
ultrasound is applied for 15 minutes at 100 W/cm² under hot conditions (20 kHz probe).

The emulsion obtained is represented in FIGS. 3 and 4.

### COMPARATIVE EXAMPLE 2

In this example, the procedure was carried out as in example 1 but without putting in surfactant and without applying ultrasound after cooling.

The protocol for the synthesis of this emulsion is as follows:
1 g of indium is weighed out in 40 ml of dodecanethiol,
the round-bottomed flask is placed on the heating plate without stirring,
the mixture is heated for 1 hour at 180° C. and stirred after ¾ hour: the solution becomes gray,
ultrasound is applied for 15 minutes at 200 W/cm² under hot conditions (20 kHz probe).

### COMPARATIVE EXAMPLE 3

The procedure was carried out as in example 1 but by applying the ultrasound solely during the cooling.

The procedure was carried out in the following way:
1 g of indium is weighed out in 40 ml of dodecanethiol,
the round-bottomed flask is placed on the heating plate without stirring,
heating is carried out at 180° C. for ¾ hour,
Triton® X100 (250 μl) is added and stirring is carried out at 180° C. for ¼ hour: the solution becomes gray,
the round-bottomed flask is moved toward the ultrasound probe and the round-bottomed flask is no longer heated,
ultrasound is applied for 15 minutes at 200 W/cm² under hot conditions (20 kHz probe).

The emulsion obtained is represented in FIGS. 5 and 6.

### COMPARATIVE EXAMPLE 4

The procedure was carried out as in comparative example 3 but by applying ultrasound while maintaining the heating.

The protocol used is as follows:
1 g of indium is weighed out in 40 ml of dodecanethiol,
the round-bottomed flask is placed on the heating plate without stirring,
heating is carried out at 180° C. for ¾ hour,
Triton® X100 (250 μl) is added and stirring is carried out at 180° C. for ¼ hour: the solution becomes gray,
ultrasound is applied for 15 minutes at 200 W/cm² under hot conditions (20 kHz probe).

The emulsion obtained is represented in FIGS. 7 to 9.

### COMPARATIVE EXAMPLE 5

The procedure was carried out as in example 1 but by applying ultrasound once more, at the end of the protocol.

The protocol used is as follows:
1 g of indium is weighed out in 40 ml of dodecanethiol,
the round-bottomed flask is placed on the heating plate without stirring,
heating is carried out at 180° C. for ¾ hour,
Triton® X100 (250 μl) is added and stirring is carried out at 180° C. for ¼ hour: the solution becomes gray,
ultrasound is applied for 15 minutes at 200 W/cm² under hot conditions (20 kHz probe),
the mixture is allowed to cool,
ultrasound is applied for 15 minutes at 20% amplitude under cold conditions,
   again:
the mixture is allowed to cool,
ultrasound is applied for 15 minutes at 20% amplitude under cold conditions.

The emulsion obtained is represented in FIGS. 10 and 11.

### COMPARATIVE EXAMPLE 6

In this example, surfactant was not used and the heating was carried out at 150° C. for 1 hour. Furthermore, ultrasound was not applied after the cooling.

The protocol used is as follows:
1 g of indium is weighed out in 40 ml of dodecanethiol,
the round-bottomed flask is placed on the heating plate without stirring,
heating is carried out at 150° C. for ¾ hour,
Triton® X100 (250 μl) is added and stirring is carried out at 150° C. for ¼ hour: the solution becomes gray,
ultrasound is applied for 15 minutes at 200 W/cm² (20 kHz probe).

The emulsion obtained is represented in FIGS. 12 and 13.

### COMPARATIVE EXAMPLE 7

The procedure was carried out as in comparative example 6 but by adding surfactant a ¼ of an hour from the end of the period of heating without ultrasound.

More specifically, the protocol is as follows:
1 g of indium is weighed out in 40 ml of dodecanethiol,
the round-bottomed flask is placed on the heating plate without stirring,
heating is carried out at 150° C. for ¾ hour,
Triton® X100 (250 μl) is added and stirring is carried out at 150° C. for ¼ hour: the solution becomes gray,
ultrasound is applied for 15 minutes at 200 W/cm² (20 kHz probe).

The emulsion obtained is represented in FIGS. 14, 15 and 16.

### COMPARATIVE EXAMPLE 8

The procedure was carried out as in comparative example 7 but by heating at 180° C. and by quenching in a bottle cooled to 0° C. for the cooling.

The protocol followed is as follows:
1 g of indium is weighed out in 40 ml of dodecanethiol,
the round-bottomed flask is placed on the heating plate without stirring,
heating is carried out at 180° C. for ¾ hour,
Triton® X100 (250 μl) is added and stirring is carried out at 180° C. for ¼ hour: the solution becomes gray,
ultrasound is applied for 15 minutes at 200 W/cm² (20 kHz probe),
the contents of the round-bottomed flask are run into a bottle cooled to 0° C.

The emulsion obtained is represented in FIGS. 17 and 18.

### COMPARATIVE EXAMPLE 9

The procedure was carried out as in comparative example 8 but the quenching is carried out in liquid nitrogen.

The protocol is as follows:
1 g of indium is weighed out in 40 ml of dodecanethiol,
the round-bottomed flask is placed on the heating plate without stirring,
heating is carried out at 180° C. for ¾ hour,
Triton® X100 (250 μl) is added and stirring is carried out at 180° C. for ¼ hour: the solution becomes gray,
ultrasound is applied for 15 minutes at 200 W/cm² (20 kHz probe),
the contents of the round-bottomed flask are run into a bottle cooled in liquid nitrogen.

The emulsion obtained is represented in FIGS. 19 and 20.

### COMPARATIVE EXAMPLE 10

The procedure was carried out as in comparative example 9 but without quenching for the cooling and by using twice as much surfactant, i.e. a surfactant/solvent ratio=1.25×10⁻².

The protocol is as follows:
1 g of indium is weighed out in 40 ml of dodecanethiol,
the round-bottomed flask is placed on the heating plate without stirring,
heating is carried out at 180° C. for ¾ hour,
Triton® X100 (500 μl) is added and stirring is carried out at 180° C. for ¼ hour: the solution becomes gray,
ultrasound is applied for 15 minutes at 200 W/cm² (20 kHz probe).

The emulsion obtained is represented in FIGS. 21 and 22.

### COMPARATIVE EXAMPLE 11

The procedure was carried out as in comparative example 10 but by using one fourth as much surfactant; i.e. a surfactant/solvent ratio=3.12×10⁻³.

The protocol is as follows:
1 g of indium is weighed out in 40 ml of dodecanethiol,
the round-bottomed flask is placed on the heating plate without stirring,
heating is carried out at 180° C. for ¾ hour,
Triton® X100 (125 μl) is added and stirring is carried out at 180° C. for ¼ hour: the solution becomes gray,
ultrasound is applied for 15 minutes at 200 W/cm² (20 kHz probe).

The emulsion obtained is represented in FIGS. 23, 24 and 25.

### COMPARATIVE EXAMPLE 12

The procedure was carried out as in comparative example 11 but by adding copper at the end of the 15 min of ultrasound.

The protocol is as follows:
1 g of indium is weighed out in 40 ml of dodecanethiol,
the round-bottomed flask is placed on the heating plate without stirring,
heating is carried out at 180° C. for ¾ hour,
Triton® X100 (125 μl) is added and stirring is carried out at 180° C. for ¼ hour: the solution becomes gray,
ultrasound is applied for 15 minutes at 200 W/cm² under hot conditions (20 kHz probe),
copper is added at the end of the 15 min.

The emulsion obtained is represented in FIGS. 26, 27 and 28.

### Results of the Syntheses of the Indium Emulsions

In the preceding examples, the power of the ultrasound used was varied.

It can be seen, from comparative examples 1 and 3, that the greater the power of the ultrasound, the smaller the size of the particles.

The influence of the surfactant was also studied.

For a reduced ultrasound power, it is seen, from comparative examples 2 and 4, that the addition of a surfactant makes it possible to reduce the size of the droplets.

Comparative examples 1 and 3 make it possible to observe the same effect.

An excessively low amount of surfactant with respect to the solvent results in particles of 3 μm being obtained (comparative example 11—ratio 3.12×10⁻³), whereas an amount twice as great makes it possible to reduce the maximum size of the particles by 2 (comparative example 4—ratio 6.25×10⁻³). Furthermore, there exists an optimum amount of surfactant as, by again multiplying by 2 the amount of surfactant (ratio 1.25×10⁻²), the phenomenon of reduction in particle size no longer occurs.

The heating temperature of the solvent was also studied.

It is seen, from the results of comparative tests 4 and 7, that, contrary to a preconception in the art consisting in heating the emulsion to a temperature lower than the melting point of the metal concerned, when use is made of a temperature for application of the ultrasound which is greater than the melting point of the indium particles, the size of the droplets is reduced.

In the preceding examples, different methods of cooling were tested in order to cool the emulsion produced.

Comparative tests 8 and 9, in comparison with comparative example 4, show that the fact of suddenly cooling the emulsion does not make it possible to freeze the size of the particles.

In order to further reduce the size of the particles, the effects of a second and even of a third application of ultrasound, this time at ambient temperature, were tested.

It is seen, from comparative example 4 and example 1 above, that the application of ultrasound a second time at ambient temperature makes it possible to reduce the size of the droplets.

The various manufacturing parameters and the size of the droplets obtained by the process according to the invention and according to the comparative examples are summarized in the following table 4.

TABLE 4

| | | Surfactant (1) | | US at t₁ | | | | |
|---|---|---|---|---|---|---|---|---|
| | | Triton X | | 180° C. | US at | Power | | |
| | | Ratio | | T > M.p. = | t₂ at | time | | |
| | Solvent (2) | (1)/(2) | T(° C.) | 156° C. | T_{ambient} | 15 min | Quenching | Sizes |
| Example 1 | Dodecanethiol | 6.25 × 10⁻³ | 180° C. | yes | yes | P2 | | 150 nm < x < 1.5 μm > |
| | | | | | | | | 1 μm 5-10% |
| Comparative | Dodecanethiol | 6.25 × 10⁻³ | 180° C. | T < 180° C. | | P1 | | Many large 5.7 μm |
| example 1 | | | | 150° C. | | | | 280 nm < x < 2.7 μm |
| Comparative | Dodecanethiol | | 180° C. | yes | | P2 | | Very rapid sedimentation |
| example 2 | | | | | | | | Essentially large |
| | | | | | | | | particles |
| Comparative | Dodecanethiol | 6.25 × 10⁻³ | 180° C. | T < 180° C. | | P2 | | A few large 5.5 μm |
| example 3 | | | | 150° C. | | | | 280 nm < x < 2 μm |
| Comparative | Dodecanethiol | 6.25 × 10⁻³ | 180° C. | yes | | P2 | | x < 1.5 μm |
| example 4 | | | | | | | | A few large 3 μm |
| Comparative | Dodecanethiol | 6.25 × 10⁻³ | 180° C. | yes | yes, | P2 | | 300 nm < x < 1.5 μm |
| example 5 | | | | | twice | | | A few large 4 μm |
| Comparative | Dodecanethiol | | 150° C. | 150° C. | | P2 | | 4-5 μm |
| example 6 | | | | | | | | 2.5 μm |
| | | | | | | | | Many < 1 μm |
| Comparative | Dodecanethiol | 6.25 × 10⁻³ | 150° C. | 150° C. | | P2 | | Dispersion++ |
| example 7 | | | | | | | | 400 nm < x < 1.8 μm |
| Comparative | Dodecanethiol | 6.25 × 10⁻³ | 180° C. | yes | | P2 | 0° C. | 400 nm < x < 2.6 μm |
| example 8 | | | | | | | | A few large 3.5 μm |
| Comparative | Dodecanethiol | 6.25 × 10⁻³ | 180° C. | yes | | P2 | Liquid | 400 nm < x < 2.8 μm |
| example 9 | | | | | | | nitrogen | |
| Comparative | Dodecanethiol | 1.25 × 10⁻² | 180° C. | yes | | P2 | | 145 nm < x < 1.3 μm + |
| example 10 | | | | | | | | a few large particles |
| Comparative | Dodecanethiol | 3.12 × 10⁻³ | 180° C. | yes | | P2 | | 180 nm < x < 1.5 μm |
| example 11 | | | | | | | | A few large at 3.5 μm |
| Comparative | Dodecanethiol | 6.25 × 10⁻³ | 180° C. | yes | | P2 | Addition | 110 nm < x < 5 μm |
| example 12 | | | | | | | of Cu | |

### EXAMPLE 2

### Preparation of a Gallium Emulsion According to the Invention

The procedure was carried out according to the following protocol:
1 g of gallium is weighed out in 40 ml of dodecanethiol,
the round-bottomed flask is placed on the heating plate without stirring,
heating is carried out at 70° C. for ¾ hour,
Triton® X100 (250 μl) is added and stirring is carried out at 70° C. for ¼ hour,
ultrasound is applied for 15 minutes at 200 W/cm² under hot conditions (20 kHz probe),
cooling is allowed to take place,
ultrasound is applied for 15 minutes at 200 W/cm² under cold conditions.

The emulsion obtained is represented in FIGS. 29, 30 and 31.

### COMPARATIVE EXAMPLE 13

The procedure was carried out as in example 2 but without a heating period before and during the application of ultrasound.

The protocol used is as follows:
1 g of gallium is weighed out in 40 ml of dodecanethiol,
Triton® X100 (250 μl) is added,
ultrasound is applied directly for 15 minutes at 200 W/cm² (20 kHz probe).

The emulsion obtained is shown in FIGS. 32, 33 and 34.

### COMPARATIVE EXAMPLE 14

The procedure was carried out as in example 2 but without application of ultrasound after cooling the emulsion.

The protocol used is as follows:
1 g of gallium is weighed out in 40 ml of dodecanethiol,
Triton® X100 (250 μl) is added,
the round-bottomed flask is placed on the heating plate without stirring,
heating is carried out at 70° C. for ¾ hour,
Triton® X100 (250 μl) is added and stirring is carried out at 70° C. for ¼ hour: the solution becomes gray,
ultrasound is applied directly for 15 minutes at 200 W/cm² under hot conditions (20 kHz probe).

The emulsion obtained is represented in FIGS. 35 and 36.

### Results of the Syntheses of the Gallium Emulsions

The melting point of gallium is 30° C. It is thus possible, from the energy dissipated by the ultrasound waves, to obtain a temperature greater than this melting point and to thus be able to produce a gallium emulsion.

At 30° C., the particles are highly polydisperse and have diameters of greater than a micrometer (comparative example 13).

Use was then made of a temperature greater than the melting point of gallium.

This synthesis corresponds to comparative example 14.

Use of this temperature made it possible to reduce the size of the particles by half, with respect to that of comparative example 13.

Subsequently, an emulsion prepared according to the process of the invention, that is to say by applying ultrasound a second time after cooling the gallium emulsion to ambient temperature, was manufactured.

The application of ultrasound a second time at ambient temperature made it possible to further lower the size of the particles and to obtain particles in a large majority of less than a micron.

The results and conditions of example 2 and examples 13 and 14 are combined in the following table 5.

TABLE 5

| | | Surfactant (1) | | | | | |
|---|---|---|---|---|---|---|---|
| | | Triton X | | | US at | Power | |
| | | Ratio | | | t₂ at | time | |
| | Solvent (2) | (1)/(2) | T(° C.) | US at t₁ | ambient | 15 min | Sizes |
| Example 2 | Dodecanethiol | 6.25 × 10⁻³ | 70° C. | yes | yes | P2 | x < 1 μm |
| | | | | | | | A few 1.8 μm |
| Comparative | Dodecanethiol | 6.25 × 10⁻³ | ambient | yes | | P2 | x < 3.3 μm |
| example 13 | | | | | | | A few 5.7 μm |
| | | | | | | | Polydispersity++ |
| Comparative | Dodecanethiol | 6.25 × 10⁻³ | 70° C. | yes | | P2 | x < 1.8 μm |
| example 14 | | | T > M.p. = | | | | A few 3.3 μm |
| | | | 30° C. | | | | |

### EXAMPLE 3

### Preparation of an Indium+Gallium Emulsion According to the Invention

The procedure was carried out according to the following protocol in order to obtain In_{0.7}Ga_{0.3}:
0.32 g of gallium and 0.78 g of indium are weighed out in 40 ml of dodecanethiol,
the round-bottomed flask is placed on the heating plate without stirring,
heating is carried out at 160° C. for ¾ hour,
Triton® X100 (250 μl) is added and stirring is carried out at 160° C. for ¼ hour,
ultrasound is applied for 15 minutes at 200 W/cm² under hot conditions (20 kHz probe).

The emulsion obtained is represented in FIGS. 37, 38 and 39.

### COMPARATIVE EXAMPLE 15

The procedure was carried out as in example 3, with application under cold conditions of ultrasound in addition.

The protocol used is as follows:
0.32 g of gallium and 0.78 g of indium are weighed out in 40 ml of dodecanethiol,
the round-bottomed flask is placed on the heating plate without stirring,
heating is carried out at 160° C. for ¾ hour,
Triton® X100 (250 μl) is added and stirring is carried out at 160° C. for ¼ hour,
ultrasound is applied for 15 minutes at 200 W/cm² under hot conditions (20 kHz probe),
cooling is allowed to take place,
ultrasound is applied for 15 minutes at 200 W/cm² under cold conditions.

The emulsion obtained is shown in FIGS. 40, 41 and 42.

1. An emulsion comprising droplets of a liquid metal and a solvent, wherein:
the metal is chosen from indium (In), gallium (Ga) and the alloys of these metals,
the solvent is chosen from:
an alkanethiol of following formula 1: 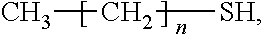
an alkanethiol ester of following formula 2: 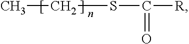
and
an alkanethiol propionic ether of following formula 3: 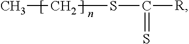
in which n is between 5 and 19 inclusive and R is a methyl or ethyl group, and
a surfactant.

2. The emulsion as claimed in claim 1, wherein the surfactant is chosen from surfactants having at least one thiol functional group, cetyltrimethylammonium bromide (CTAB), a surfactant of the family of the sorbitan monostearates, a surfactant of the family of the polysorbates, an octylphenol ethoxylate surfactant, a surfactant comprising a pyrrolidol group and mixtures thereof.

3. The emulsion as claimed in claim 1, wherein 90% by number of the liquid metal droplets have a mean diameter of less than 1 μm.

4. The emulsion as claimed in claim 1, wherein the solvent has a boiling point greater by at least 5° C. than the melting point of the In or Ga metal or of the In—Ga alloy present in the emulsion.

5. The emulsion as claimed in claim 1, wherein the solvent is dodecanethiol.

6. The emulsion as claimed in claim 1, wherein the surfactant is Triton® X100.

7. The emulsion as claimed in claim 1, wherein the metal is indium.

8. The emulsion as claimed in claim 1, wherein the metal is gallium.

9. The emulsion as claimed in claim 1, wherein the metal is an alloy of indium and gallium.

10. The emulsion as claimed in claim 9, wherein the alloy of indium and gallium comprises 70% by weight of indium and 30% by weight of gallium, with respect to the total weight of indium and gallium.

11. The emulsion as claimed in claim 1, wherein it additionally comprises particles of metal copper Cu(0), or of a precursor of the latter, having a size of between 10 nm and 500 nm.

12. The emulsion as claimed in claim 11, wherein the metal copper precursor is copper chloride (CuCl₂), copper nitrate (Cu(NO₃)₂), a copper carboxylate of formula Cu(OOCR)₂, where R is a linear C₁ to C₃ alkyl group, a copper β-diketonate of formula Cu(R₁COCH₂COR₂)₂, where R₁ and R₂ are a copper alkoxide of formula Cu(OR₃)₂, in which R₃ is a linear C₁ to C₄ alkyl, or of formula Cu(OR₄)₂NR₅, in which R₄ is a linear C₁ to C₂ alkyl and R₅ is H or a linear C₂ alcohol group or a linear C₁ to C₄ alkyl, an alcohol of formula HOCH₂CH₂NR₆R₇, with R₆ and R₇ which are identical or different and are chosen, independently of one another, from H, Me, Et, Pr or Bu.

13. The emulsion as claimed in claim 12, wherein the metal precursor is chosen from the copper alkoxides Cu(OCH₂CH₂)₂NH, Cu(OCH₂CH₂)₂NnBu or Cu(OCH₂CH₂)₂NEt or a mixture of these.

14. The emulsion as claimed in claim 1, wherein the surfactant/solvent ratio by volume is between 10⁻⁴ and 10⁻² inclusive.

15. A process for the manufacture of an emulsion comprising droplets of a liquid metal, comprising the following steps:
a) introduction of a metal chosen from indium, gallium and the alloys of these metals into a solvent chosen from:
an alkanethiol of following formula 1: 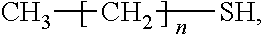
an alkanethiol ester of following formula 2: 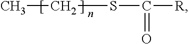
and
an alkanethiol propionic ether of following formula 3: 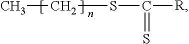
in which n is between 5 and 19 inclusive and R is a methyl or ethyl group,
b) heating the suspension obtained in step a) to a temperature greater than the melting point of the metal and lower than the temperature of the solvent,
c) addition of a surfactant,
d) application of ultrasound for 15 minutes, while maintaining the same temperature as in steps b) and c), with a 20 kHz probe, amplitude of 75%,
e) cooling, by natural cooling, the emulsion obtained in step d), and
f) application of ultrasound for 15 minutes, at ambient temperature, with a 20 kHz probe, amplitude 20%.

16. The process as claimed in claim 15, wherein the surfactant is chosen from surfactants having at least one thiol functional group, cetyltrimethylammonium bromide (CTAB), a surfactant of the family of the sorbitan monostearates, a surfactant of the family of the polysorbates, an octylphenol ethoxylate surfactant, a surfactant comprising a pyrrolidol group and mixtures thereof.

17. The process as claimed in claim 15, wherein the metal is indium and the heating temperature in steps b), c) and d) is 180° C.

18. The process as claimed in claim 15, wherein the metal is gallium and the heating temperature in steps b), c) and d) is 70° C.

19. The process as claimed in claim 15, wherein the metal is an alloy of indium and gallium and in that, in step a), particles of a preformed alloy of indium and gallium or particles of indium and particles of gallium in the desired proportions are introduced, or else an emulsion as claimed in claim 7 is mixed with an emulsion as claimed in claim 8, in the necessary proportions of indium and gallium to form the desired alloy of indium and gallium, and in that the heating temperature in steps b), c) and d) is 180° C.

20. The process as claimed in claim 15, additionally comprising, after step c), a step of addition of particles of copper or of a copper precursor chosen from particles of copper chloride (CuCl₂), copper nitrate (Cu(NO₃)₂), a copper carboxylate of formula Cu(OOCR)₂, where R is a linear C₁ to C₃ alkyl group, a copper β-diketonate of formula Cu(R₁COCH₂COR₂)₂, where R₁ and R₂ are a copper alkoxide of formula Cu(OR₃)₂, in which R₃ is a linear C₁ to C₄ alkyl, or of formula Cu(OR₄)₂NR₅, in which R₄ is a linear C₁ to C₂ alkyl and R₅ is H or a linear C₂ alcohol group or a linear C₁ to C₄ alkyl, an alcohol of formula HOCH₂CH₂NR₆R₇, with R₆ and R₇ which are identical or different and are chosen, independently of one another, from H, Me, Et, Pr or Bu.

21. The process as claimed in claim 20, wherein the copper precursor is chosen from the copper alkoxides Cu(OCH₂CH₂)₂NH, Cu(OCH₂CH₂)₂NnBu or Cu(OCH₂CH₂)₂NEt or a mixture of these.

22. The process as claimed in claim 15, wherein the solvent is dodecanethiol.

23. The process as claimed in claim 15, wherein the surfactant is Triton® X100.

24. A process for the deposition of a film made of a metal chosen from indium, gallium and the alloys of these, optionally with Cu, comprising the following steps:
a) deposition, on at least one surface of a substrate, of an emulsion of the desired metal as claimed in claim 1, and
b) heat treatment of the at least one surface.

25. The process as claimed in claim 24, wherein the deposition step a) is carried out by screen printing, paste coating or spraying said emulsion.

26. The process as claimed in claim 24, wherein the heat treatment step b) is carried out at a temperature of greater than 120° C. but of less than 300° C. for a period of time of between 10 and 60 min inclusive.

27. A process for the deposition of a Cu—In—Ga—X film, where X is S and/or Se, comprising the following steps:
a) deposition, on at least one surface of a substrate, of an emulsion as claimed in claim 11, and
b) heat treatment of said at least one surface in the presence of vapor of X.

28. A process for the manufacture of an active layer of a photovoltaic device, comprising a step of deposition of a Cu—In—Ga—X film, where X is S or Se, on at least one surface of a substrate by the process as claimed in claim 27.

29. A process for the manufacture of a photovoltaic device, characterized in that it comprises a step of deposition of a Cu—In—Ga—X film, where X is S or Se, on at least one surface of a substrate by the process as claimed in claim 28.

30. The process as claimed in claim 28, characterized in that the photovoltaic device is a photovoltaic battery, cell or panel.

31. The use of an emulsion as claimed in claim 1 for the deposition of a film of a metal chosen from indium, gallium and the alloys of these on the surface of at least one substrate.

32. The emulsion as claimed in claim 11, wherein the metal copper precursor is copper acetate.

33. The emulsion as claimed in claim 11, wherein the metal copper precursor is copper acetylacetonate.

34. The process as claimed in claim 20, wherein the copper precursor is copper acetate.

35. The process as claimed in claim 20, wherein the metal copper precursor is copper acetylacetonate.
